(19) United States
(12) Patent Application Publication
(10) Pub. No.: US 2017/0187001 A1
(43) Pub. Date: Jun. 29, 2017

(54) LIGHT EMITTING DIODE, DISPLAY SUBSTRATE AND DISPLAY DEVICE HAVING THE SAME, AND FABRICATING METHOD THEREOF

(71) Applicant: BOE TECHNOLOGY GROUP CO., LTD., Beijing (CN)

(72) Inventors: Jingang Fang, Beijing (CN); Xiaodi Liu, Beijing (CN); Dongfang Wang, Beijing (CN); Lungpao Hsin, Beijing (CN)

(73) Assignee: BOE TECHNOLOGY GROUP CO., LTD., Beijing (CN)

(21) Appl. No.: 15/303,009

(22) PCT Filed: Apr. 6, 2016
(86) PCT No.: PCT/CN2016/078554

§ 371 Date: Oct. 9, 2016

(30) Foreign Application Priority Data
Jul. 27, 2015 (CN) 201510446925.3

(51) Int. Cl. H01L 51/52; H01L 51/56; H01L 27/32

(52) U.S. Cl. CPC H01L 51/5265; H01L 51/5218; H01L 27/3211; H01L 27/3244; H01L 51/56; H01L 2251/308; H01L 2251/305; H01L 2251/558; H01L 2227/323

(57) ABSTRACT

The present application discloses a light emitting diode comprising a plurality of sub-pixels comprising a first electrode layer, wherein the first electrode layer is a reflective electrode layer; a second electrode layer; a light emitting layer between the first electrode layer and the second electrode layer; a first microcavity tuning layer sandwiched by the first electrode layer and the light emitting layer within the plurality of sub-pixels; and a second microcavity tuning layer sandwiched by the first microcavity tuning layer and the light emitting layer within at least one of the plurality of sub-pixels, and the first microcavity tuning layer is sandwiched by the first electrode layer and the second microcavity tuning layer within the at least one of the plurality of sub-pixels. The first microcavity tuning layer is made of a material including a transparent conductive material in a first state and the second microcavity tuning layer is made of a material including a transparent conductive material in a second state, the first state and the second state are different states selected from a crystalline state and an amorphous state.

### CROSS-REFERENCE TO RELATED APPLICATION

This application claims priority to Chinese Patent Application No. 201510446925.3, filed Jul. 27, 2015, the contents of which are incorporated by reference in the entirety.

### TECHNICAL FIELD

The present invention relates to display technology, more particularly, to a light emitting diode, a display substrate and a display device having the same, and a fabricating method thereof.

### BACKGROUND

As compared to other display devices such as liquid crystal display (LCD) devices, the organic light emitting diode (OLED) display devices are self-emitting apparatuses that do not require a backlight. Having the advantages of fast response, a wider viewing angle, high brightness, more vivid color rendering, thinner and lighter, they have found a wide range of applications in display field.

Typically, a convention OLED includes an anode, a light emitting layer and a cathode. The light emitting layer often includes an emitting layer (EML), and optionally one or more of a hole injection layer (HIL), a hole transport layer (HTL), an electron transport layer (ETL), and an electrode injection layer (EIL). When a voltage is applied between the cathode and the anode, charge carriers (electrons and holes) are injected from the cathode and the anode into the emitting layer. The electrons and holes are recombined in the emitting layer, which emits light. Some OLED devices also include one or more microcavities.

### SUMMARY

In one aspect, the present invention provides a light emitting diode comprising a plurality of sub-pixels comprising a first electrode layer, wherein the first electrode layer is a reflective electrode layer; a second electrode layer; a light emitting layer between the first electrode layer and the second electrode layer; a first microcavity tuning layer sandwiched by the first electrode layer and the light emitting layer within the plurality of sub-pixels; and a second microcavity tuning layer sandwiched by the first microcavity tuning layer and the light emitting layer within at least one of the plurality of sub-pixels, and the first microcavity tuning layer is sandwiched by the first electrode layer and the second microcavity tuning layer within the at least one of the plurality of sub-pixels. The first microcavity tuning layer is made of a material comprising a transparent conductive material in a first state and the second microcavity tuning layer is made of a material comprising a transparent conductive material in a second state, the first state and the second state are different states selected from a crystalline state and an amorphous state.

Optionally, the first microcavity layer is made of material comprising a crystalline transparent conductive oxide and the second microcavity tuning layer is made of a material comprising an amorphous transparent conductive oxide.

Optionally, the crystalline transparent conductive oxide is a crystalline transparent conductive indium tin oxide.

Optionally, the amorphous transparent conductive oxide is selected from one or a combination of an amorphous transparent conductive indium tin oxide, an amorphous transparent conductive indium tin zinc oxide, an amorphous transparent conductive indium zinc oxide, and an amorphous transparent conductive aluminum zinc oxide.

Optionally, the first electrode layer has a thickness in the range of about 50 nm to about 300 nm.

Optionally, the first microcavity tuning layer has a thickness in the range of about 5 nm to about 15 nm.

Optionally, the second microcavity tuning layer has a thickness in the range of about 50 nm to about 70 nm.

Optionally, the first electrode layer is made of a material comprising an alloy having a reflectivity higher than 90%.

Optionally, a first sub-pixel has the first microcavity, and a second sub-pixel and a third sub-pixel have the second microcavity.

Optionally, the first sub-pixel is a green sub-pixel, the second sub-pixel is a red sub-pixel, and the third sub-pixel is a blue sub-pixel.

In another aspect, the present invention provides a method of fabricating a display substrate comprising an array of pixels, each pixel comprising at least three sub-pixels, the method comprising forming a first electrode layer, wherein the first electrode layer is a reflective electrode layer; forming a microcavity tuning layer comprising a first microcavity tuning layer and a second microcavity tuning layer on the first electrode layer; forming a light emitting layer on a side of the microcavity tuning layer distal to the first electrode layer; and forming a second electrode layer on a side of the light emitting layer distal to the microcavity tuning layer. The first microcavity tuning layer is sandwiched by the first electrode layer and the light emitting layer within three sub-pixels. The second microcavity tuning layer is sandwiched by the first microcavity tuning layer and the light emitting layer within at least one of three sub-pixels, and the first microcavity tuning layer is sandwiched by the first electrode layer and the second microcavity tuning layer within the at least one of three sub-pixels. The first microcavity tuning layer is made of a material comprising a transparent conductive material in a first state and the second microcavity tuning layer is made of a material comprising a transparent conductive material in a second state, the first state and the second state are different states selected from a crystalline state and an amorphous state.

Optionally, the first microcavity layer is made of a material comprising a crystalline transparent conductive oxide and the second microcavity tuning layer is made of a material comprising an amorphous transparent conductive oxide.

Optionally, the crystalline transparent conductive oxide is a crystalline transparent conductive indium tin oxide.

Optionally, the amorphous transparent conductive oxide is selected from one or a combination of an amorphous transparent conductive indium tin oxide, an amorphous transparent conductive indium tin zinc oxide, an amorphous transparent conductive indium zinc oxide, and an amorphous transparent conductive aluminum zinc oxide.

Optionally, the first electrode layer, the first microcavity tuning layer and the second microcavity tuning layer are patterned using a single mask.

Optionally, the single mask is a gray-tone mask plate or a half-tone mask plate, and the step of forming a microcavity tuning layer comprises using a gray-tone mask plate or a half-tone mask plate to obtain a pattern, wherein the pattern comprises a first section corresponding to the first microcavity, the second section corresponding to the second microcavity, and a third section corresponding to the remaining portion of the photoresist layer.

Optionally, the step of forming a microcavity tuning layer comprising forming a reflective electrode material layer; forming a first microcavity tuning material layer on the reflective electrode material layer; forming a second microcavity tuning material layer on a side of the first microcavity tuning layer distal to the reflective electrode material layer; forming a photoresist layer on a side of the second microcavity tuning material layer distal to the first microcavity tuning material layer; exposing the photoresist layer with a gray-tone mask plate or a half-tone mask plate; developing the exposed photoresist layer to obtain a pattern, wherein the pattern comprises a first section corresponding to the first microcavity, the second section corresponding to the second microcavity, and a third section corresponding to the remaining portion of the photoresist layer; removing the photoresist layer in the third section and partially removing the photoresist layer in the first section; etching the second microcavity tuning material layer, the first microcavity tuning material layer, and the reflective electrode material layer in the third section thereby forming the first electrode layer; removing the photoresist layer in the first section thereby exposing the second microcavity tuning material layer in the first section; etching the second microcavity tuning material layer in the first section thereby exposing the first microcavity tuning material layer in the first section; and removing the photoresist layer in the second section.

Optionally, the step of etching the second microcavity tuning material layer, the first microcavity tuning material layer, and the reflective electrode material layer in the third section comprises sequentially etching the third section with a second microcavity tuning material etchant, a first microcavity tuning material etchant, and a reflective electrode material etchant.

Optionally, the step of etching the second microcavity tuning material layer in the first section comprises etching the first section with a second microcavity tuning material etchant.

Optionally, a first sub-pixel has the first microcavity, and a second sub-pixel and a third sub-pixel have the second microcavity.

Optionally, the first sub-pixel is a green sub-pixel, the second sub-pixel is a red sub-pixel, and the third sub-pixel is a blue sub-pixel.

Optionally, the first electrode layer is made of a material comprising an alloy having a reflectivity higher than 90%.

Optionally, the first electrode layer has a thickness in the range of about 50 nm to about 300 nm.

Optionally, the first microcavity tuning layer has a thickness in the range of about 5 nm to about 15 nm.

Optionally, the second microcavity tuning layer has a thickness in the range of about 50 nm to about 70 nm.

In another aspect, the present invention provides a display substrate comprising the light emitting diode described herein or manufactured be a method described herein.

In another aspect, the present invention provides a display device comprising the array substrate described herein.

### BRIEF DESCRIPTION OF THE FIGURES

The following drawings are merely examples for illustrative purposes according to various disclosed embodiments and are not intended to limit the scope of the present invention.

FIG. 1 is a flow chart illustrating a method of fabricating a display substrate in some embodiments.

FIG. 2 is a flow chart illustrating a method of fabricating a display substrate in some embodiments.

FIG. 3 is a diagram illustrating the structure of various layers of a display substrate in some embodiments.

FIG. 4 is a diagram illustrating the structure of various layers of a display substrate in some embodiments.

FIG. 5 is a diagram illustrating the structure of various layers of a display substrate in some embodiments.

FIG. 6 is a diagram illustrating the structure of various layers of a display substrate in some embodiments.

FIG. 7 is a diagram illustrating the structure of various layers of a display substrate in some embodiments.

FIG. 8 is a diagram illustrating the structure of a display substrate having a reflective electrode layer, a first microcavity tuning layer and a second microcavity tuning layer in some embodiments.

### DETAILED DESCRIPTION

The disclosure will now describe more specifically with reference to the following embodiments. It is to be noted that the following descriptions of some embodiments are presented herein for purpose of illustration and description only. It is not intended to be exhaustive or to be limited to the precise form disclosed.

In making a conventional microcavity OLED device, multiple patterning processes involving multiple mask plates are required to form a reflective electrode layer and multiple microcavity tuning layers in a display substrate. The microcavity tuning layer typically has a small thickness. When multiple etching processes are involved, it is difficult to control the etching processes to obtain a desired tuning layer thickness precisely, leading to a lower color purity and a lower light emitting efficiency. These shortcomings of the conventional OLED result in a complex manufacturing process and very high manufacturing costs.

The present disclosure provides a superior light emitting diode, a display substrate and a display device having the same, and a superior fabricating method for making the light emitting diode. In one aspect, the present disclosure provides a light emitting diode having multiple microcavity tuning layers, at least two of which differ from each other by the crystalline states of microcavity tuning materials used therein. For example, the light emitting diode may have one microcavity tuning layer made of a material including a substantially crystalline material, and another made of a material including a substantially amorphous material. As used herein, the term “crystalline material” refers to both a material in a polycrystalline state and a material in a single-crystalline state. Optionally, a crystalline material may include one or more molecules of another material. As used herein, the term “amorphous material” refers to both a material in a completely disordered non-crystalline state, and a fine crystal grain such as micro-crystal, nano-crystal, and a material having short range ordered structure and the like. Different crystalline states result in detectably different electrical characteristics, such as reactivity to various etchants and/or electrical conductivity. For example, an amorphous material may react to a wider range of etchants or weaker etchants, whereas a crystalline material may react to a smaller range of etchants or stronger etchants. Optionally, the amorphous material is an amorphous indium tin oxide and the crystalline material is a polycrystalline indium tin oxide. Optionally, the amorphous indium tin oxide may be etched by oxalic acid, hydrochloric acid, and nitric acid, and the polycrystalline indium tin oxide may be etched by nitric acid but not oxalic acid or hydrochloric acid. Optionally, the polycrystalline indium tin oxide may be etched by aqua agia, but not nitric acid, oxalic acid, or hydrochloric acid. Optionally, when a same material is used, a crystalline material has a higher electrical conductivity than an amorphous material. As used herein, the term “substantially” means and includes mostly, essentially, fully, or entirely. By way of example, the phrase “a substantially crystalline material” may refer to a material with a portion in a crystalline state, the portion in the range of from about 90% (e.g., about 95%, about 99%) by volume up to and including about 100% by volume of the material, and a remaining portion (i.e., in the range of from about 10% (e.g., about 5%, about 1%) to about 0% by volume, respectively) in an amorphous state.

In some embodiments, the light emitting diode may have one microcavity tuning layer made of a material including a crystalline transparent conductive material, and another made of a material including an amorphous transparent conductive material. For example, the light emitting diode may include a plurality of sub-pixels in each pixel unit; a first microcavity tuning layer and a second microcavity tuning layer in each pixel unit. The first microcavity tuning layer is sandwiched by the first electrode layer (e.g., a reflective electrode layer) and the light emitting layer within the plurality of sub-pixels, and the second microcavity tuning layer sandwiched by the first microcavity tuning layer and the light emitting layer within at least one (e.g., one, two, or three) of the plurality of sub-pixels. Optionally, the first microcavity layer is made of material comprising a crystalline transparent conductive oxide and the second microcavity tuning layer is made of a material comprising an amorphous transparent conductive oxide. Optionally, the second microcavity layer is made of material comprising a crystalline transparent conductive oxide and the first microcavity tuning layer is made of a material comprising an amorphous transparent conductive oxide.

In some embodiments, the light emitting diode includes a first electrode layer, wherein the first electrode layer is a reflective electrode layer; a second electrode layer; a light emitting layer between the first electrode layer and the second electrode layer; a first microcavity tuning layer sandwiched by the first electrode layer and the light emitting layer within the plurality of sub-pixels; and a second microcavity tuning layer sandwiched by the first microcavity tuning layer and the light emitting layer within at least one of the plurality of sub-pixels, and the first microcavity tuning layer is sandwiched by the first electrode layer and the second microcavity tuning layer within the at least another of the three sub-pixels. The first microcavity tuning layer is made of a material including a transparent conductive material in a first state and the second microcavity tuning layer is made of a material including a transparent conductive material in a second state, the first state and the second state are different states selected from a crystalline state and an amorphous state. For example, the first microcavity layer may be made of material having a crystalline transparent conductive oxide and the second microcavity tuning layer may be made of a material having an amorphous transparent conductive oxide. Optionally, the second microcavity layer is made of material comprising a crystalline transparent conductive oxide and the first microcavity tuning layer is made of a material comprising an amorphous transparent conductive oxide.

In another aspect, the present disclosure provides a method of fabricating a display substrate having an array of pixels, each pixel having three sub-pixels. In some embodiments, the fabricating method according to the present disclosure includes forming a first electrode layer (e.g., a reflective electrode layer); forming a microcavity tuning layer including a first microcavity tuning layer and a second microcavity tuning layer on the reflective electrode layer, forming a light emitting layer on a side of the microcavity tuning layer distal to the reflective electrode layer; and forming a second electrode layer on a side of the light emitting layer distal to the microcavity tuning layer. The first microcavity tuning layer is sandwiched by the reflective electrode layer and the light emitting layer within at least one of the three sub-pixels (e.g., all three sub-pixels). The second microcavity tuning layer is sandwiched by the first microcavity tuning layer and the light emitting layer within at least one of the three sub-pixels (e.g., a second sub-pixel and/or a third sub-pixel), and the first microcavity tuning layer is sandwiched by the reflective electrode layer and the second microcavity tuning layer within the at least one of the three sub-pixels. The first microcavity tuning layer is made of a material including a transparent conductive material in a first state and the second microcavity tuning layer is made of a material including a transparent conductive material in a second state, the first state and the second state are different states selected from a crystalline state and an amorphous state. For example, the first microcavity layer may be made of material having a crystalline transparent conductive oxide and the second microcavity tuning layer may be made of a material having an amorphous transparent conductive oxide. Accordingly, a first microcavity is formed between the reflective electrode layer and the second electrode layer within the at least one of the three sub-pixels (e.g., all three sub-pixels); and a second microcavity is formed between the reflective electrode layer and the second electrode layer within the at least one of the three sub-pixels (e.g., a second sub-pixel and/or a third sub-pixel); the second microcavity has a microcavity length larger than that of the first microcavity. The reflective electrode layer, the first microcavity tuning layer and the second microcavity tuning layer are formed in a single process (e.g., patterned using a single mask). Optionally, the reflective electrode layer comprises three sub-electrodes corresponding to three sub-pixels, respectively.

Various appropriate methods may be used for making an amorphous transparent conductive layer or a crystalline transparent conductive layer. The crystalline state of the layer may be affected by various factors such as the temperature of the base substrate, the deposition rate of the material, the thickness of the layer, and the humidity level during the deposition process. Optionally, the amorphous transparent conductive layer and the crystalline transparent conductive layer may be made by adjusting the humidity level during the deposition process such as a sputtering process. When the humidity level is low, the crystalline transparent conductive layer may be formed. When the humidity level is increased during the sputtering process, the water molecule (e.g., the oxygen atom in the water molecule) occupies the crystal lattice of the transparent conductive material (e.g., indium tin oxide), introducing stress into the crystal lattice. Thus, by adjusting the humidity level during the sputtering process, the amorphous transparent conductive layer can be obtained. The crystalline state of the transparent conductive layer may result in different reactivity to different etchant, accordingly a particular transparent conductive layer may be selectively etched using an appropriate etchant. For example, when oxalic acid is used as the etchant, an amorphous transparent conductive material layer may be etched and removed, whereas a crystalline transparent conductive layer remains intact and is not etched.

In some embodiments, the reflective electrode layer and multiple microcavity tuning layers are formed in a single process (e.g., patterned using a single mask), greatly simplifies the fabricating process and lowers the manufacturing costs. In another aspect, the present disclosure provides a light emitting diode with multiple microcavity tuning layers of higher precision.

Optionally, the first microcavity layer and the second microcavity tuning layer are made of a same material. Optionally, the first microcavity layer and the second microcavity tuning layer are made of different materials. Optionally, the first microcavity layer and the second microcavity tuning layer are made of different forms of a same material, e.g., a crystalline form and an amorphous form of a same material such as a metal oxide. Optionally, the first microcavity layer and the second microcavity tuning layer are made of different forms of different materials, e.g, a crystalline form of one material (e.g., a first metal oxide) and an amorphous form of another material (e.g., a second metal oxide).

Optionally, the first microcavity tuning layer may have a single-layer structure or a stacked-layer structure including two or more sub-layers. Optionally, the second microcavity tuning layer may have a single-layer structure or a stacked-layer structure including two or more sub-layers.

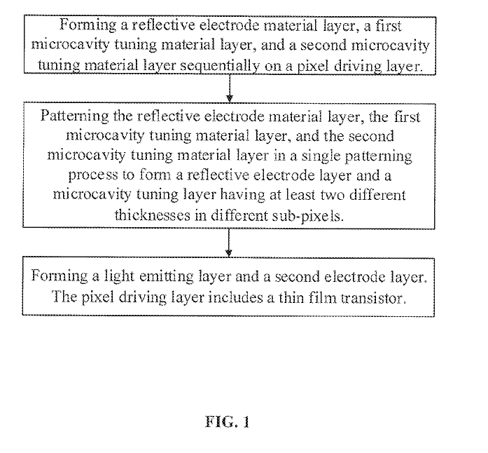

FIG. 1 is a flow chart illustrating a method of fabricating a display substrate in some embodiments. Referring to FIG. 1, the method in the embodiment includes forming a reflective electrode material layer, a first microcavity tuning material layer, and a second microcavity tuning material layer sequentially on a pixel driving layer; patterning the reflective electrode material layer, the first microcavity tuning material layer, and the second microcavity tuning material layer in a single patterning process to form a reflective electrode layer and a microcavity tuning layer having at least two different thicknesses in different sub-pixels; and forming a light emitting layer and a second electrode layer. The microcavity tuning layer includes a first microcavity tuning layer. Optionally, the microcavity tuning layer includes a first microcavity tuning layer and a second microcavity tuning layer.

The present method enables a single patterning process for forming a reflective electrode layer and a microcavity tuning layer having at least two different thicknesses in different sub-pixel regions. The present method thus significantly simplifies the fabricating process and lowers the manufacturing costs, providing a light emitting diode with multiple microcavity tuning layers of higher precision.

In some embodiments, the method includes using a gray-tone mask plate or a half-tone mask plate to obtain a pattern, wherein the pattern includes a first section corresponding to the first microcavity, the second section corresponding to the second microcavity, and a third section corresponding to the remaining portion of the photoresist layer.

Optionally, the method includes one or a combination of the following steps: forming a reflective electrode material layer; forming a first microcavity tuning material layer on the reflective electrode layer; forming a second microcavity tuning material layer on a side of the first microcavity tuning layer distal to the reflective electrode material layer; forming a photoresist layer on a side of the second microcavity tuning material layer distal to the first microcavity tuning material layer; exposing the photoresist layer with a mask plate (e.g., a single mask plate); and developing the exposed photoresist layer to obtain a pattern. The pattern includes a first section corresponding to the first microcavity, the second section corresponding to the second microcavity, and a third section corresponding to the remaining portion of the photoresist layer.

Optionally, the step of exposing the photoresist layer with a mask plate includes exposing the photoresist layer with a gray-tone mask plate or a half-tone mask plate.

Optionally, the method further includes one or a combination of the following steps: removing the photoresist layer in the third section and partially removing the photoresist layer in the first section; etching the second microcavity tuning material layer, the first microcavity tuning material layer, and the reflective electrode material layer in the third section thereby forming the reflective electrode layer; removing the photoresist layer in the first section (e.g., by ashing the photoresist layer) thereby exposing the second microcavity tuning material layer in the first section; etching the second microcavity tuning material layer in the first section thereby exposing the first microcavity tuning material layer in the first section; and removing the photoresist layer in the second section.

Optionally, the step of etching the second microcavity tuning material layer, the first microcavity tuning material layer, and the reflective electrode material layer in the third section includes sequentially etching the third section with a second microcavity tuning material etchant, a first microcavity tuning material etchant, and a reflective electrode material etchant.

Optionally, the step of etching the second microcavity tuning material layer in the first section includes etching the first section with a second microcavity tuning material etchant.

Optionally, a first sub-pixel contains the first microcavity, and a second sub-pixel and a third sub-pixel contain the second microcavity. Optionally, the first sub-pixel is a green sub-pixel, the second sub-pixel is a red sub-pixel, and the third sub-pixel is a blue sub-pixel.

Optionally, the reflective electrode layer is made of a material comprising an alloy having a reflectivity higher than 90%, e.g., higher than 92%, higher than 94%, higher than 96%, higher than 98%, or higher than 99%.

Optionally, the first microcavity layer is made of material including a crystalline transparent conductive oxide and the second microcavity tuning layer is made of a material including an amorphous transparent conductive oxide. Optionally, the crystalline transparent conductive oxide is a crystalline transparent conductive indium tin oxide. Optionally, the amorphous transparent conductive oxide is selected from one or a combination of an amorphous transparent conductive indium tin oxide, an amorphous transparent conductive indium tin zinc oxide, an amorphous transparent conductive indium zinc oxide, and an amorphous transparent conductive aluminum zinc oxide.

Optionally, the reflective electrode has a thickness in the range of about 50 nm to about 300 nm, e.g., about 50 nm to about 100 nm, about 100 nm to about 200 nm, or about 200 nm to about 300 nm.

Optionally, the first microcavity tuning layer has a thickness in the range of about 5 nm to about 15 nm, e.g., about 5 nm to about 10 nm, about 10 nm to about 15 nm, or about 7.5 nm to about 12.5 nm.

Optionally, the second microcavity tuning layer has a thickness in the range of about 50 nm to about 70 nm, e.g., about 50 nm to about 60 nm, about 60 nm to about 70 nm, about 55 nm to about 65 nm.

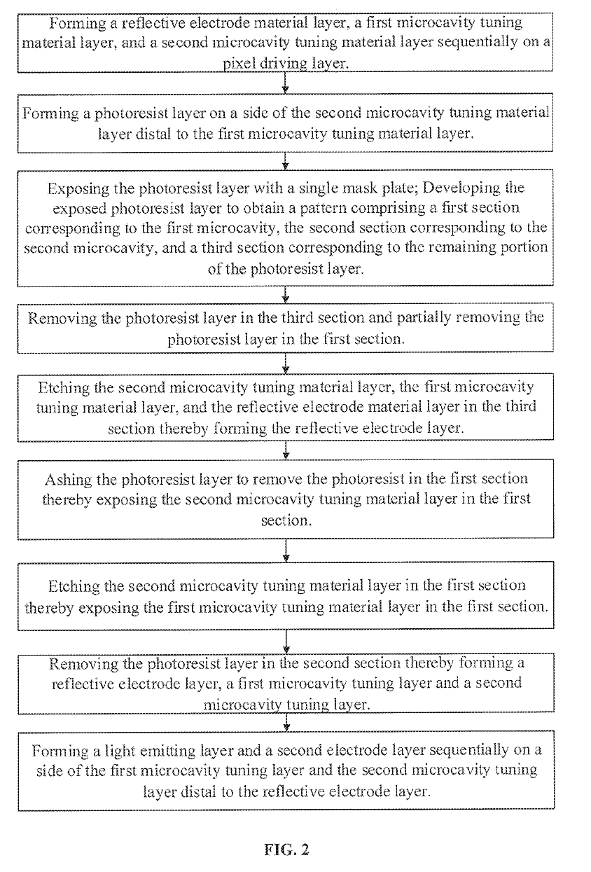

FIG. 2 is a flow chart illustrating a method of fabricating a display substrate in some embodiments. Referring to FIG. 2, the method in the embodiment includes forming a reflective electrode material layer, a first microcavity tuning material layer, and a second microcavity tuning material layer sequentially on a pixel driving layer; forming a photoresist layer on a side of the second microcavity tuning material layer distal to the first microcavity tuning material layer; exposing the photoresist layer with a single mask plate; developing the exposed photoresist layer to obtain a pattern comprising a first section corresponding to the first microcavity, the second section corresponding to the second microcavity, and a third section corresponding to the remaining portion of the photoresist layer; removing the photoresist layer in the third section and partially removing the photoresist layer in the first section; etching the second microcavity tuning material layer, the first microcavity tuning material layer, and the reflective electrode material layer in the third section thereby forming the reflective electrode layer; ashing the photoresist layer to remove the photoresist in the first section thereby exposing the second microcavity tuning material layer in the first section; etching the second microcavity tuning material layer in the first section thereby exposing the first microcavity tuning material layer in the first section; removing the photoresist layer in the second section thereby forming a reflective electrode layer, a first microcavity tuning layer and a second microcavity tuning layer; and forming a light emitting layer and a second electrode layer sequentially on a side of the first microcavity tuning layer and the second microcavity tuning layer distal to the reflective electrode layer.

In some embodiments, the step of forming a reflective electrode material layer, a first microcavity tuning material layer, and a second microcavity tuning material layer sequentially on a pixel driving layer includes forming a reflective electrode material layer on a pixel driving layer. For example, the reflective electrode material may be deposited on the pixel driving layer by sputtering, vapor deposition, or coating. Optionally, the reflective electrode material layer has a thickness in the range of about 50 nm to about 300 nm, e.g., about 50 nm to about 100 nm, about 100 nm to about 200 nm, or about 200 nm to about 300 nm.

The pixel driving layer is formed on a base substrate (e.g., a glass substrate or a quartz substrate.

The reflective electrode layer is an oxidation-resistant layer having a high reflectivity and high work function. Optionally, the reflective electrode material layer is made of a material comprising an alloy having a reflectivity higher than 90%, e.g., higher than 92%, higher than 94%, higher than 96%, higher than 98%, or higher than 99%. Examples of appropriate alloys for making the reflective electrode layer include, but are not limited to, aluminum alloys, silver alloys, and molybdenum alloys. Optionally, the reflective electrode material layer is made of a material which can be specifically etched by a reflective electrode layer etchant (e.g., an aluminum etching solution), but not by other etchants such as those for etching microcavity tuning layers.

The OLED may be a conventional OLED or an inverted OLED. Optionally, the OLED is a conventional OLED, and the reflective electrode is an anode. Optionally, the OLED is an inverted OLED, and the reflective electrode is a cathode.

In some embodiments, the step of forming a reflective electrode material layer, a first microcavity tuning material layer, and a second microcavity tuning material layer sequentially on a pixel driving layer further includes forming a first microcavity tuning material layer on a side of the reflective electrode material layer distal to the pixel driving layer. For example, the first microcavity tuning material may be deposited on the reflective electrode material layer by sputtering, vapor deposition, or coating. Optionally, the first microcavity tuning material layer has a thickness in the range of about 5 nm to about 15 nm, e.g., about 5 nm to about 10 nm, about 10 nm to about 15 nm, or about 7.5 nm to about 12.5 nm.

Optionally, the first microcavity tuning material layer is a crystalline transparent conductive oxide layer, e.g., a crystalline transparent conductive indium tin oxide layer.

Optionally, the first microcavity tuning material layer is made of a material which can be specifically etched by a first microcavity tuning material layer etchant (e.g., a crystalline indium tin oxide etching solution such as a nitric acid-containing solution), but not by other etchants such as those for etching the reflective electrode material or the second microcavity tuning material.

In some embodiments, the step of forming a reflective electrode material layer, a first microcavity tuning material layer, and a second microcavity tuning material layer sequentially on a pixel driving layer further includes forming a second microcavity tuning material layer on a side of the first microcavity tuning material layer distal to the reflective electrode material layer. For example, the second microcavity tuning material may be deposited on the first microcavity tuning material layer by sputtering, vapor deposition, or coating. Optionally, the second microcavity tuning material layer has a thickness in the range of about 50 nm to about 70 nm, e.g., about 50 nm to about 60 nm, about 60 nm to about 70 nm, about 55 nm to about 65 nm.

Optionally, the second microcavity tuning material layer is an amorphous transparent conductive oxide layer. Examples of suitable amorphous transparent conductive oxides include, but are not limited to, an amorphous transparent conductive indium tin oxide, an amorphous transparent conductive indium tin zinc oxide, an amorphous transparent conductive indium zinc oxide, and an amorphous transparent conductive aluminum zinc oxide. Optionally, the second microcavity tuning material layer has a light transmission rate higher than 85%, e.g., higher than 90%, higher than 95%, or higher than 98%.

Optionally, the second microcavity tuning material layer is made of a material which can be specifically etched by a second microcavity tuning material layer etchant (e.g., an amorphous indium tin oxide etching solution such as a solution containing oxalic acid and/or hydrochloric acid), but not by other etchants such as those for etching the reflective electrode material or the first microcavity tuning material.

To prevent oxidation of the reflective electrode material layer, the first microcavity tuning material layer, and the second microcavity tuning material layer, these layers may be formed and patterned in certain temperature ranges and atmosphere.

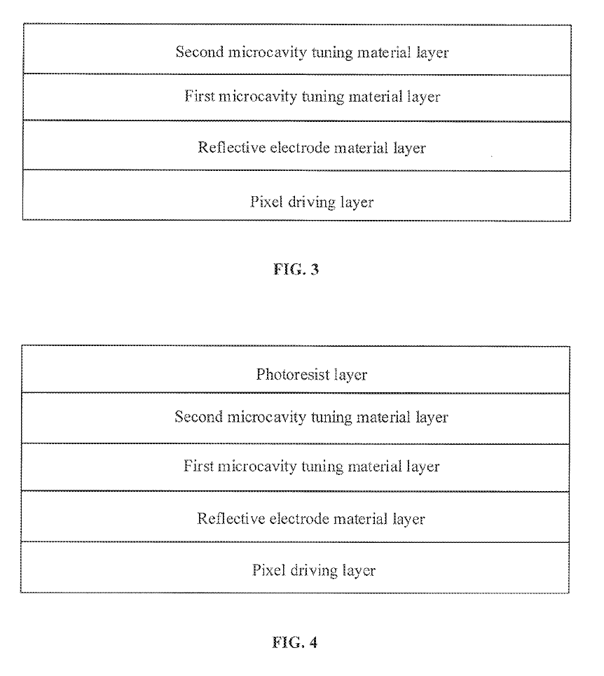

FIG. 3 is a diagram illustrating the structure of a display substrate in some embodiments having the reflective electrode material layer, the first microcavity tuning material layer, and the second microcavity tuning material layer.

FIG. 4 is a diagram illustrating the structure of a display substrate in some embodiments having the photoresist layer, the reflective electrode material layer, the first microcavity tuning material layer, and the second microcavity tuning material layer. The photoresist layer may be formed by various methods, such as by coating. An appropriate thickness of the photoresist layer suitable for subsequent patterning steps may be selected.

In some embodiments, the step of exposing the photoresist layer with a single mask plate includes exposing the photoresist layer with a gray-tone mask plate or a half-tone mask plate. Optionally, the gray-tone mask plate (or the half-tone mask plate) includes a transmissive section, a semi-light-shielding section, and a light-shielding section. When a positive photoresist is used, the light-shielding section corresponds to the second section corresponding to the second microcavity (e.g., sub-pixel(s) in which the second microcavity tuning layer is sandwiched by the first microcavity tuning layer and the light emitting layer), the semi-light-shielding section corresponds to the first section corresponding to the first microcavity (e.g., sub-pixel(s) in which the first microcavity tuning layer is sandwiched by the reflective electrode layer and the light emitting layer), and the transmissive section corresponds to the third section corresponding to the remaining portion of the photoresist layer. When a negative photoresist is used, the transmissive section corresponds to the second section corresponding to the second microcavity (e.g., sub-pixel(s) in which the second microcavity tuning layer is sandwiched by the first microcavity tuning layer and the light emitting layer), the semi-light-shielding section corresponds to the first section corresponding to the first microcavity (e.g., sub-pixel(s) in which the first microcavity tuning layer is sandwiched by the reflective electrode layer and the light emitting layer), and the light-shielding section corresponds to the third section corresponding to the remaining portion of the photoresist layer.

The exposed photoresist layer is then developed. The photoresist layer in the third section is completely removed. The photoresist layer in the first section is partially removed (e.g., resulting in a reduced thickness of the photoresist layer). The photoresist layer in the second section in substantially not removed. The structure of the display substrate after this step is shown in FIG. 5.

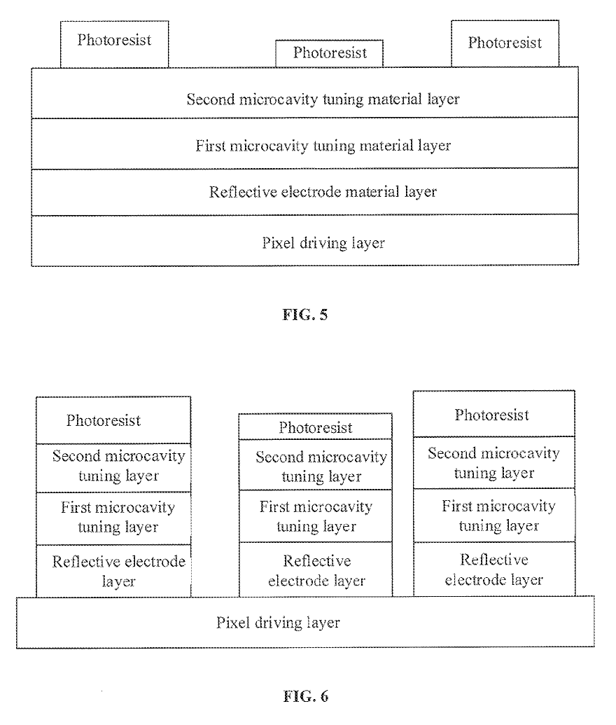

As discussed above, subsequently the photoresist layer is sequentially etched by a second microcavity tuning material etchant, a first microcavity tuning material etchant, and a reflective electrode material etchant. The photoresist is completely removed in the third section. The second microcavity tuning material layer, the first microcavity tuning material layer, and the reflective electrode material layer in the third section are not protected by the photoresist layer, and are dissolved by the etchants in the third section. The reflective electrode material layer is patterned to form a reflective electrode layer. The structure of the display substrate after this step is shown in FIG. 6.

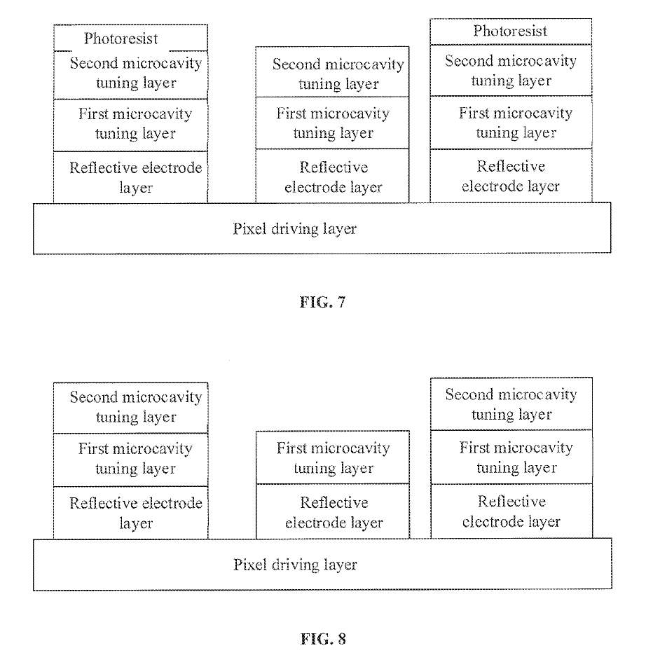

In some embodiments, the display substrate is then subject to ashing. The photoresist layer in the first section is partially removed and has a reduced thickness, whereas the photoresist layer in the second section in substantially not removed. During the ashing, the photoresist layer in the first section is removed, exposing the second microcavity tuning material layer in the first section. The photoresist layer in the second section, having a larger thickness, is only partially removed during etched. Thus, the photoresist layer in the second section is still protected by the photoresist layer after the ashing step. The structure of the display substrate after this step is shown in FIG. 7.

The display substrate is then subject to a second etching process using an etchant specific for etching the second microcavity tuning material. The exposed second microcavity tuning material layer in the first section is removed by the second etching process. Because the etchant in the step is specific for etching the second microcavity tuning material but not the first microcavity tuning material or the reflective electrode layer, the first microcavity tuning material layer underneath the second microcavity tuning material layer in the first section remains substantially intact. The reflective electrode material layer in the third section and the first microcavity tuning material layer in the second section remain substantially intact.

After the second etching process, the photoresist layer in the second section is removed. As shown in FIG. 8, the display substrate contains a reflective electrode layer, a first microcavity tuning layer and a second microcavity tuning layer. In the second section, the display substrate has a microcavity tuning layer including a first microcavity tuning layer and a second microcavity tuning layer. In the first section, the display substrate has a microcavity tuning layer including a first microcavity tuning layer but not a second microcavity tuning layer. The first section corresponds to the first microcavity. The second section corresponds to the second microcavity. The second microcavity has a microcavity length larger than that of the first microcavity. The display substrate in the embodiment includes a microcavity tuning layer having different microcavity lengths in different sub-pixels, and different microcavity tuning layer thicknesses in different sub-pixels.

The light emitting layer and the second electrode layer may be formed by various methods such as vapor deposition.

In some embodiments, the first sub-pixel is a green sub-pixel, the second sub-pixel is a red sub-pixel, and the third sub-pixel is a blue sub-pixel. Optionally, the first sub-pixel has a first microcavity, and the second sub-pixel and the third sub-pixel have a second microcavity.

The present method enables a single patterning process for forming a reflective electrode layer and a microcavity tuning layer having at least two different thicknesses in different sub-pixel regions. The present method thus significantly simplifies the fabricating process and lowers the manufacturing costs, providing a light emitting diode with multiple microcavity tuning layers of higher precision.

In some embodiments, the fabricating method further includes forming a gate electrode layer on the base substrate. In some embodiments, the step of forming the gate electrode layer includes cleansing the base substrate; depositing a gate electrode material layer on the base substrate (e.g., by sputtering or vapor deposition); and patterning the gate electrode material layer thereby forming a gate electrode layer (e.g., by lithography such as a wet etching process). Examples of gate electrode materials include, but are not limited to, aluminum, chromium, tungsten, titanium, tantalum, molybdenum, copper, and alloys containing the same. Optionally, the gate electrode layer may have a single-layer structure or a stacked-layer structure including two or more sub-layers. Optionally, the gate electrode layer has a thickness in the range of about 200 nm to about 1000 nm.

In some embodiments, the fabricating method further includes forming a gate insulating layer on the base substrate (e.g., on a side of the gate electrode layer distal to the base substrate). For example, a gate insulating material may be deposited on the base substrate by a plasma-enhanced chemical vapor deposition (PECVD) process. Examples of gate insulating materials include, but are not limited to, silicon oxide, silicon nitride (e.g., Si₃N₄), silicon oxynitride (SiOₓN_{y}). Optionally, the gate insulating layer may have a single-layer structure or a stacked-layer structure including two or more sub-layers. Optionally, the gate insulating layer has a thickness in the range of about 5 nm to about 300 nm.

In some embodiments, the fabricating method further includes forming an active layer on the base substrate (e.g., on a side of the gate insulating layer distal to the gate electrode layer). For example, an oxide active layer material may be deposited on the base substrate by, e.g., vapor deposition. Optionally, the step of forming the active layer includes depositing an active layer material layer on the base substrate (e.g., by vapor deposition); and patterning the active layer material layer thereby forming an active layer (e.g., by lithography such as a wet etching process). Examples of active layer materials include, but are not limited to, metal oxide semi-conductive materials such as indium gallium zinc oxide, zinc oxide, zinc oxynitride, and indium tin zinc oxide. Optionally, the gate insulating layer has a thickness in the range of about 5 nm to about 250 nm.

In some embodiments, the fabricating method further includes forming an etching stop layer on the base substrate (e.g., on a side of the active layer distal to the gate insulating layer). Optionally, the step of forming the etching stop layer includes depositing an etching stop layer material layer on the base substrate (e.g., by vapor deposition); and patterning the etching stop layer material layer thereby forming an etching stop layer (e.g., by lithography such as a dry etching process). For example, the etching stop layer material may be deposited on the base substrate by a PECVD process.

In some embodiments, the fabricating method further includes forming a source electrode and a drain electrode on the base substrate (e.g., on a side of the etching stop layer distal to the active layer). Optionally, the step of forming the source/drain electrode includes depositing a source/drain electrode material on the base substrate (e.g., by sputtering); and patterning the source/drain electrode material layer thereby forming the source/drain electrode (e.g., by an etching process).

In some embodiments, the fabricating method further includes forming a passivation layer on the base substrate (e.g., on a side of the source/drain electrode distal to the base substrate). Optionally, the step of forming the passivation layer includes depositing a passivation material layer on the base substrate (e.g., by PECVD); and patterning the passivation material layer thereby forming a passivation layer (e.g., by etching).

In some embodiments, the fabricating method further includes forming a pixel driving layer on the base substrate (e.g., on a side of the reflective electrode layer proximal to the base substrate). Optionally, the step of forming the pixel driving layer includes patterning a pixel driving material layer thereby forming a pixel driving layer.

Various alternative embodiments may be practiced. Optionally, the thin film transistor is a bottom-gate type thin film transistor. Optionally, the thin film transistor is a top-gate type thin film transistor. Optionally, the active layer is made of a metal oxide material. Optionally, the active layer is made of a polycrystalline silicon or an amorphous silicon material. Optionally, the method includes forming an etching stop layer. Optionally, the method does not involve forming an etching stop layer. Optionally, the pixel driving layer includes an array of thin film transistors, and/or a passivation layer. Optionally, the pixel driving layer further includes a planarization layer and a water/oxygen barrier layer, etc.

In some embodiments, the fabricating method further includes forming an anode on the base substrate (e.g., on a side of the pixel driving layer distal to the base substrate). For example, an anode material layer may be sputtered on the base substrate, and the anode material layer may be patterned to form the anode.

In some embodiments, the fabricating method further includes forming a pixel definition layer on the base substrate (e.g., on a side of the anode distal to the base substrate). For example, a pixel definition material layer having a thickness in the range of about 1 μm to about 4 μm is deposited on the base substrate, followed by patterning the pixel definition material layer to form the pixel definition layer.

In some embodiments, the fabricating method further includes forming a light emitting layer on the base substrate (e.g., on a side of the pixel definition layer distal to the base substrate). Optionally, the step of forming the light emitting layer includes depositing organic light emitting materials on the base substrate (e.g., by vapor deposition in vacuum and heat). Optionally, the step includes sequentially depositing an electron transport layer (e.g., at 190° C.), an emissive layer, and a hole transport layer (e.g., at 170° C.) in vacuum (e.g., 1×10⁻⁵ Pa). Optionally, the hole transport layer is a N,N′-Bis-(1-naphthalenyl)-N,N′-bis-phenyl-(1,1′-biphenyl)-4,4′-diamine (NPB) layer having a thickness of about 50 nm. Optionally, the electron transport layer is a 4,7-diphenyl-1,10-phenanthroline (Bphen) layer having a thickness of about 25 nm. Optionally, the light emitting layer includes a host material doped with a phosphor. Optionally, the light emitting layer in the green sub-pixel includes a CBP:(ppy)₂Ir(acac) layer of about 25 nm thickness. Optionally, the light emitting layer in the blue sub-pixel includes a CBP:FIrpic layer of about 25 nm thickness. Optionally, the light emitting layer in the red sub-pixel includes a CBP:Btp₂Ir(acac) layer of about 25 nm thickness. CBP stands for 4,4′-Bis(N-carbazolyl)-1,1′-biphenyl or derivatives thereof; (ppy)₂Ir(acac) stands for Bis[2-(2-pyridinyl-N)phenyl-C](2,4-pentanedionato-O²,O⁴)iridium(III) or derivatives thereof; FIrpic stands for Bis[2-(4,6-difluorophenyl)pyridinato-C²,N](picolinato)iridium(III) or derivatives thereof; and Btp2Ir(acac) stands for bis(2-(2′-benzo[4,5-a]thienyl) pyridinato-N,C³′) iridium (acetylacetonate) or derivatives thereof. Optionally, the step of forming the light emitting layer further includes one or more of the forming steps: forming a hole injection layer, forming a hole transport layer, forming an electron transport layer, and forming an electron injection layer.

In some embodiments, the fabricating method further includes forming a cathode layer. Examples of cathode materials include, but are not limited to, indium zinc oxide and aluminum zinc oxide. Optionally, the cathode layer is a transparent electrode layer. Optionally, the cathode layer is a transflective electrode layer. Optionally, the cathode layer has a thickness in the range of about 50 nm to about 200 nm.

In some embodiments, the display substrate further includes a color filter. Optionally, the display substrate includes a package substrate having a color filter. In some embodiments, the display substrate does not include a color filter.

In another aspect, the present disclosure provides a method of fabricating a package substrate having a color filter. Optionally, the method includes forming a black matrix layer on a package substrate; forming a color filter layer on the package substrate; and forming a post spacer layer on the substrate. Optionally, an organic black material having a thickness of about 1 μm is coated on the package substrate, the organic black material layer is then patterned to form the black matrix layer. Optionally, a red color filter film, a green color filter film, and a blue color filter film (each having a thickness in the range of about 1 μm to about 3 μm) are coated on the package substrate, and are patterned to form the color filter layer. The post spacer layer prevents damages caused by particles during assembly of the display substrate and the package substrate. Optionally, a post spacer material layer having a thickness in the range of about 3 μm to about 5 μm is coated on the package substrate, and is patterned to form the post spacer layer. The post spacer layer is formed in regions of the package substrate corresponding to the black matrix layer.

The display substrate and the package substrate are assembled together to form a display panel. Optionally, a transparent cover plate is attached to the assembled display panel. Optionally, the transparent cover plate is made of a material containing a glass (e.g., a glass made by Corning Inc. or Asahi Glass Co.), or other suitable quartz glass. Optionally, the transparent cover plate has a thickness in the range of about 50 μm to about 1000 μm.

In another aspect, the present disclosure provides a superior light emitting diode. In some embodiments, the light emitting diode includes a reflective electrode layer; a light emitting layer; a first microcavity tuning layer sandwiched by the first electrode layer and the light emitting layer within at least one of the three sub-pixels (e.g., all three sub-pixels); and a second microcavity tuning layer sandwiched by the first microcavity tuning layer and the light emitting layer within at least one of the three sub-pixels, and the first microcavity tuning layer is sandwiched by the first electrode layer and the second microcavity tuning layer within the at least one of the three sub-pixels. The first microcavity tuning layer is made of a material including a transparent conductive material in a first state and the second microcavity tuning layer is made of a material including a transparent conductive material in a second state, the first state and the second state are different states selected from a crystalline state and an amorphous state. For example, the first microcavity layer may be made of material having a crystalline transparent conductive oxide and the second microcavity tuning layer may be made of a material having an amorphous transparent conductive oxide. A first microcavity is formed between the first electrode layer and the second electrode layer within the at least one of the three sub-pixels (e.g., all three sub-pixels). A second microcavity is formed between the first electrode layer and the second electrode layer within the at least one of the three sub-pixels; the second microcavity has a microcavity length larger than that of the first microcavity.

Optionally, a first sub-pixel has the first microcavity, and a second sub-pixel and a third sub-pixel have the second microcavity. For example, the first sub-pixel is a green sub-pixel, the second sub-pixel is a red sub-pixel, and the third sub-pixel is a blue sub-pixel.

Optionally, the reflective electrode material layer is made of a material comprising an alloy having a reflectivity higher than 90%, e.g., higher than 92%, higher than 94%, higher than 96%, higher than 98%, or higher than 99%. Examples of appropriate alloys for making the reflective electrode layer include, but are not limited to, aluminum alloys, silver alloys, and molybdenum alloys. Optionally, the reflective electrode material layer is made of a material which can be specifically etched by a reflective electrode layer etchant (e.g., an aluminum etching solution), but not by other etchants such as those for etching microcavity tuning layers.

Optionally, the reflective electrode has a thickness in the range of about 50 nm to about 300 nm, e.g., about 50 nm to about 100 nm, about 100 nm to about 200 nm, or about 200 nm to about 300 nm. Optionally, the first microcavity tuning layer has a thickness in the range of about 5 nm to about 15 nm, e.g., about 5 nm to about 10 nm, about 10 nm to about 15 nm, or about 7.5 nm to about 12.5 nm. Optionally, the second microcavity tuning layer has a thickness in the range of about 50 nm to about 70 nm, e.g., about 50 nm to about 60 nm, about 60 nm to about 70 nm, about 55 nm to about 65 nm. Optionally, the second microcavity tuning layer has a light transmission rate higher than 85%, e.g., higher than 90%, higher than 95%, or higher than 98%.

Optionally, the first microcavity tuning layer is a crystalline transparent conductive oxide layer, e.g., a crystalline transparent conductive indium tin oxide layer. Optionally, the second microcavity tuning material layer is an amorphous transparent conductive oxide layer. Examples of suitable amorphous transparent conductive oxides include, but are not limited to, an amorphous transparent conductive indium tin oxide, an amorphous transparent conductive indium tin zinc oxide, an amorphous transparent conductive indium zinc oxide, and an amorphous transparent conductive aluminum zinc oxide.

In another aspect, the present disclosure provides a display substrate having a light emitting diode described herein or manufactured by a method described herein. In another aspect, the present disclosure provides a display device having a display substrate described herein. Examples of appropriate display devices include, but are not limited to, a smartphone, a tablet computer, a smart TV, etc.

FIG. 8 is a diagram illustrating the structure of a display substrate having a reflective electrode layer, a first microcavity tuning layer and a second microcavity tuning layer in some embodiments. Referring to FIG. 8, the display substrate in the embodiment includes a base substrate, a pixel driving layer on the base substrate, a reflective electrode layer on a side of the pixel driving layer distal to the base substrate, and a microcavity tuning layer on a side of the reflective electrode layer distal to the base substrate. The microcavity tuning layer in the embodiment has different thicknesses in different sub-pixels of the display substrate, e.g., it includes a first microcavity tuning layer and a second microcavity tuning layer. In some sub-pixel(s), the microcavity tuning layer only contains a first microcavity tuning layer. In other sub-pixel(s), the microcavity tuning layer contains both a first microcavity tuning layer and a second microcavity tuning layer. The display substrate in the embodiment further includes a light emitting layer and a second electrode.

The base substrate may be a glass substrate or a quartz substrate. The reflective electrode layer is an oxidation-resistant layer having a high reflectivity and high work function. Optionally, the reflective electrode material layer is made of a material comprising an alloy having a reflectivity higher than 90%, e.g., higher than 92%, higher than 94%, higher than 96%, higher than 98%, or higher than 99%. Examples of appropriate alloys for making the reflective electrode layer include, but are not limited to, aluminum alloys, silver alloys, and molybdenum alloys. Optionally, the first microcavity tuning layer is a crystalline transparent conductive oxide layer, e.g., a crystalline transparent conductive indium tin oxide layer. Optionally, the second microcavity tuning material layer is an amorphous transparent conductive oxide layer. Examples of suitable amorphous transparent conductive oxides include, but are not limited to, an amorphous transparent conductive indium tin oxide, an amorphous transparent conductive indium tin zinc oxide, an amorphous transparent conductive indium zinc oxide, and an amorphous transparent conductive aluminum zinc oxide. Optionally, the first microcavity tuning layer has a thickness in the range of about 5 nm to about 15 nm. Optionally, the second microcavity tuning layer has a thickness in the range of about 50 nm to about 70 nm.

A first microcavity is formed between the first electrode layer and the second electrode layer within the at least one of the three sub-pixels (e.g., all three sub-pixels). A second microcavity is formed between the first electrode layer and the second electrode layer within the at least one of the three sub-pixels (e.g., sub-pixels having both a first microcavity tuning layer and a second microcavity tuning layer). The second microcavity has a microcavity length larger than that of the first microcavity.

Optionally, a first sub-pixel has the first microcavity, and a second sub-pixel and a third sub-pixel have the second microcavity. For example, the first sub-pixel is a green sub-pixel, the second sub-pixel is a red sub-pixel, and the third sub-pixel is a blue sub-pixel.

The present display substrate includes a microcavity tuning layer having different thicknesses in different sub-pixels of the display substrate, e.g., a first microcavity tuning layer and a second microcavity tuning layer, resulting in different microcavities having different microcavity lengths. Different microcavities correspond to different sub-pixels, tailored for generating resonant light of different colors. The present display substrate provides superior light emission efficiency and color purity.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A light emitting diode comprising a plurality of sub-pixels, comprising:
a first electrode layer, wherein the first electrode layer is a reflective electrode layer;
a second electrode layer;
a light emitting layer between the first electrode layer and the second electrode layer;
a first microcavity tuning layer sandwiched by the first electrode layer and the light emitting layer within the plurality of sub-pixels; and
a second microcavity tuning layer sandwiched by the first microcavity tuning layer and the light emitting layer within at least one of the plurality of sub-pixels, and the first microcavity tuning layer is sandwiched by the first electrode layer and the second microcavity tuning layer within the at least one of the plurality of sub-pixels;
wherein the first microcavity tuning layer is made of a material comprising a transparent conductive material in a first state and the second microcavity tuning layer is made of a material comprising a transparent conductive material in a second state, the first state and the second state are different states selected from a crystalline state and an amorphous state.

2. The light emitting diode of claim 1, wherein the first microcavity layer is made of a material comprising a crystalline transparent conductive oxide and the second microcavity tuning layer is made of a material comprising an amorphous transparent conductive oxide.

3. The light emitting diode of claim 1, wherein the crystalline transparent conductive oxide is a crystalline transparent conductive indium tin oxide.

4. The light emitting diode of claim 1, wherein the amorphous transparent conductive oxide is selected from one or a combination of an amorphous transparent conductive indium tin oxide, an amorphous transparent conductive indium tin zinc oxide, an amorphous transparent conductive indium zinc oxide, and an amorphous transparent conductive aluminum zinc oxide.

5. (canceled)

6. The light emitting diode of claim 1, wherein the first microcavity tuning layer has a thickness in the range of about 5 nm to about 15 nm.

7. The light emitting diode of claim 1, wherein the second microcavity tuning layer has a thickness in the range of about 50 nm to about 70 nm.

8. The light emitting diode of claim 1, wherein the first electrode layer is made of a material comprising an alloy having a reflectivity higher than 90%.

9. (canceled)

10. (canceled)

11. A display substrate comprising the light emitting diode of claim 1.

12. A display device comprising the array substrate of claim 11.

13. A method of fabricating a display substrate comprising an array of pixels, each pixel comprising at least three sub-pixels, the method comprising:
forming a first electrode layer, wherein the first electrode layer is a reflective electrode layer;
forming a microcavity tuning layer comprising a first microcavity tuning layer and a second microcavity tuning layer on the first electrode layer;
forming a light emitting layer on a side of the microcavity tuning layer distal to the first electrode layer; and
forming a second electrode layer on a side of the light emitting layer distal to the microcavity tuning layer;
wherein the first microcavity tuning layer is sandwiched by the first electrode layer and the light emitting layer within three sub-pixels;
the second microcavity tuning layer is sandwiched by the first microcavity tuning layer and the light emitting layer within at least one of three sub-pixels, and the first microcavity tuning layer is sandwiched by the first electrode layer and the second microcavity tuning layer within the at least one of three sub-pixels; and
the first microcavity tuning layer is made of a material comprising a transparent conductive material in a first state and the second microcavity tuning layer is made of a material comprising a transparent conductive material in a second state, the first state and the second state are different states selected from a crystalline state and an amorphous state.

14. The method of claim 13, wherein the first microcavity layer is made of a material comprising a crystalline transparent conductive oxide and the second microcavity tuning layer is made of a material comprising an amorphous transparent conductive oxide.

15. The method of claim 13, wherein the crystalline transparent conductive oxide is a crystalline transparent conductive indium tin oxide.

16. The method of claim 13, wherein the amorphous transparent conductive oxide is selected from one or a combination of an amorphous transparent conductive indium tin oxide, an amorphous transparent conductive indium tin zinc oxide, an amorphous transparent conductive indium zinc oxide, and an amorphous transparent conductive aluminum zinc oxide.

17. The method of claim 13, wherein the first electrode layer, the first microcavity tuning layer and the second microcavity tuning layer are patterned using a single mask.

18. The method of claim 13, wherein the single mask is a gray-tone mask plate or a half-tone mask plate, and the step of forming a microcavity tuning layer comprises using a gray-tone mask plate or a half-tone mask plate to obtain a pattern, wherein the pattern comprises a first section corresponding to the first microcavity, the second section corresponding to the second microcavity, and a third section corresponding to the remaining portion of the photoresist layer.

19. The method of claim 13, wherein the step of forming a microcavity tuning layer comprising:
forming a reflective electrode material layer;
forming a first microcavity tuning material layer on the reflective electrode material layer;
forming a second microcavity tuning material layer on a side of the first microcavity tuning layer distal to the reflective electrode material layer;
forming a photoresist layer on a side of the second microcavity tuning material layer distal to the first microcavity tuning material layer;
exposing the photoresist layer with a gray-tone mask plate or a half-tone mask plate;
developing the exposed photoresist layer to obtain a pattern, wherein the pattern comprises a first section corresponding to the first microcavity, the second section corresponding to the second microcavity, and a third section corresponding to the remaining portion of the photoresist layer;
removing the photoresist layer in the third section and partially removing the photoresist layer in the first section;
etching the second microcavity tuning material layer, the first microcavity tuning material layer, and the reflective electrode material layer in the third section thereby forming the first electrode layer;
removing the photoresist layer in the first section thereby exposing the second microcavity tuning material layer in the first section;
etching the second microcavity tuning material layer in the first section thereby exposing the first microcavity tuning material layer in the first section; and
removing the photoresist layer in the second section.

20. The method of claim 19, wherein the step of etching the second microcavity tuning material layer, the first microcavity tuning material layer, and the reflective electrode material layer in the third section comprises sequentially etching the third section with a second microcavity tuning material etchant, a first microcavity tuning material etchant, and a reflective electrode material etchant.

21. The method of claim 19, wherein the step of etching the second microcavity tuning material layer in the first section comprises etching the first section with a second microcavity tuning material etchant.

22. (canceled)

23. (canceled)

24. (canceled)

25. (canceled)

26. The method of claim 13, wherein the first microcavity tuning layer has a thickness in the range of about 5 nm to about 15 nm.

27. The method of claim 13, wherein the second microcavity tuning layer has a thickness in the range of about 50 nm to about 70 nm.
